(19) United States
(12) Patent Application Publication
(10) Pub. No.: US 2024/0194645 A1
(43) Pub. Date: Jun. 13, 2024

(54) U-TURN CIRCUITRY TO CONVERT INTER-LAYER CONNECTIONS OF AN INTEGRATED CIRCUIT DEVICE TO INTRA-LAYER CONNECTIONS

(71) Applicant: XILINX, INC., San Jose, CA (US)

(72) Inventors: Jay T. YOUNG, Broomfield, CO (US); Davis Boyd MOORE, Longmont, CO (US); Sundeep Ram Gopal AGARWAL, Hyderabad (IN); Brian C. GAIDE, Erie, CO (US)

(21) Appl. No.: 18/079,631

(22) Filed: Dec. 12, 2022

(51) Int. Cl. H01L 25/065; G11C 5/02; G11C 5/06; H01L 23/48; H01L 27/02; H01L 27/06

(52) U.S. Cl. CPC H01L 25/0657; G11C 5/025; G11C 5/063; H01L 23/481; H01L 27/0207; H01L 27/0688; H01L 2225/06506

(57) ABSTRACT

An integrated circuit (IC) device includes a block of integrated circuitry that includes functional circuitry and configurable interface circuitry. The configurable interface circuitry includes output circuitry that routes a node of the functional circuitry to an output node of the block, and input circuitry that selectively routes the output node of the block or an input node of the block to the functional circuitry. The output circuitry may route a selectable subset of multiple nodes of the functional circuitry to respective output nodes of the block, and the input circuitry may be configured to route the output nodes of the block back to the functional circuitry in the absence of an adjacent block (e.g., to repurpose the output circuitry), or in addition to interfacing with the adjacent block.

### TECHNICAL FIELD

Examples of the present disclosure generally relate to circuitry to convert interlayer connections of an integrated circuit device to intra-layer connections.

### BACKGROUND

An integrated circuit (IC) device may include vertically stacked IC chips, where each IC chip includes functional circuitry and inter-layer connection circuitry to provide vertical connections between adjacent IC chips. In some situations, the inter-layer connection circuitry may be unused or underutilized.

### SUMMARY

Circuitry to convert inter-layer connections of an integrated circuit device to intra-layer connections are described. One example described herein is an integrated circuit (IC) device that includes a block of integrated circuitry that includes functional circuitry and configurable interface circuitry, where the configurable interface circuitry includes output circuitry that route a node of the functional circuitry to an output node of the block and input circuitry that routes a selectable one of the output node of the block and an input node of the first block to the functional circuitry.

Another example described herein is an IC device that includes a stack of multiple blocks of integrated circuitry, wherein a first one of the blocks comprises functional circuitry and configurable interface circuitry, where the configurable interface circuitry routes a first node of the functional circuitry to an output node of the first block and routes a selectable one of the output node of the first block and an input node of the first block to a second node of the functional circuitry, where the output node and the input node of the first block are coupled to respective input and output nodes of an adjacent one of the blocks.

Another example described herein is an IC device that includes a stack of multiple blocks of integrated circuitry, where each block includes functional circuitry and configurable interface circuitry, and where the configurable interface circuitry includes output circuitry that routes n output nodes of the functional circuitry to n respective output nodes of the block, and n blocks of input multiplexer circuitry, each including a first input coupled to a respective one of n output nodes of the block, a second input coupled to a respective one of the n input nodes of the block, and an output coupled to a respect one of n input nodes of the functional circuitry.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a block diagram of an integrated circuit (IC) device that includes stacked blocks of integrated circuitry that include functional circuitry and configurable interface circuitry, according to an embodiment.

FIG. 2 is a block diagram of an adjacent pair of the blocks, according to an embodiment.

FIG. 3 is a logic diagram of the adjacent pair of blocks, according to an embodiment.

FIG. 4 is a logic diagram in which the configurable interface circuitry includes min multiplexer circuitry, according to an embodiment.

FIG. 5 is a logic diagram of connections between the configurable interface circuitry of an adjacent pair of the blocks, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

An integrated circuit (IC) chip designed for a 3-dimensional (3D) or stacked IC device may include inter-layer connection circuitry (e.g., vertical connections and supporting multiplexers) to connect neighboring or adjacent chip layers on either side of the IC chip. In some situations, the inter-layer connection circuitry is unused or underutilized. For example, if the IC chip is the upper-most IC chip in a stack (i.e., where there is no connectivity above the IC chip), or if the IC chip is the lowest chip in a stack (i.e., where there is sparse connectivity with a base layer), half of the inter-layer connection circuitry may go unused. As another example, if the IC chip is used in a 2-dimensional scenario, all of the inter-layer connection circuitry may be unused.

Embodiments herein describe techniques to repurpose inter-layer connection circuitry to provide intra-layer connections (i.e., connections within functional circuitry or within a fabric of an IC chip).

Embodiments herein include configurable circuitry that selectively reroutes an output of inter-layer connection circuitry back to the functional circuitry or fabric of an IC chip. The configurable circuitry may be referred to as U-turn or loop-back circuitry. The configurable circuitry may include a 2-input multiplexer for each inter-layer output. The configurable circuitry may utilize relatively little area and may consume relatively little additional power, with relatively little delay.

Embodiments herein may be useful to convert inter-layer connection circuitry to intra-layer connection circuitry, such as when an IC chip is used in a 2D application. Embodiments herein may also be useful to use inter-layer connection circuitry for both inter-layer connections and intra-layer connections (i.e., when the IC chip is used in a 3D or stacked application). In other words, embodiments herein may be useful when an IC chip is used in 3D stack or a 2D application.

Embodiments herein may be useful to improve design routability and/or performance of an IC chip. Results on a fabricated design suite designed specifically for fabric routability testing by increasing connectivity and logic utilization showed an increase in designs routed of between 10% and 20% where the baseline is designed to route approximately 50% of the designs. For example the baseline architecture routed 50 of 100 designs and the addition described here routed improved to ˜60 of 100 designs attempted.

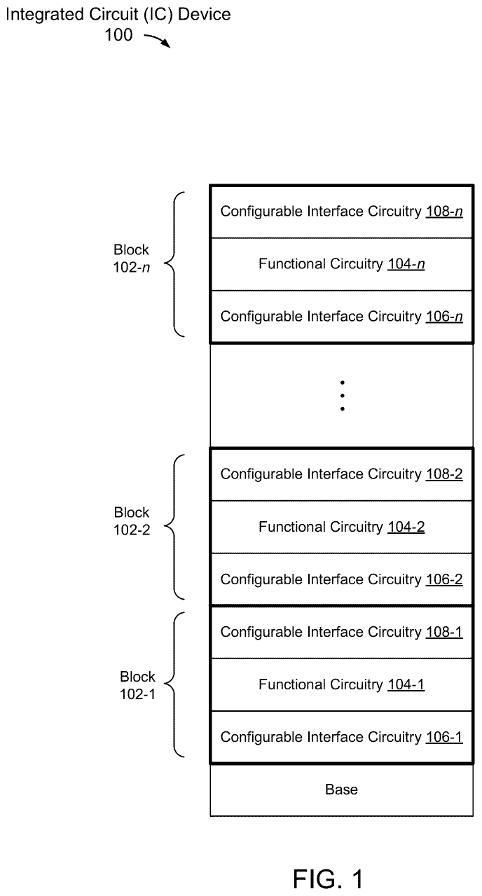

FIG. 1 is a block diagram of an integrated circuit (IC) device 100 that includes stacked blocks 102-1 through 102-n of integrated circuitry that include respective functional circuitry 104-1 through 104-n, configurable interface circuitry 106-1 through 106-n, and configurable interface circuitry 108-1 through 108-n, according to an embodiment.

Blocks 102-1 through 102-n may be collectively referred to as blocks 102. Functional circuitry 104-1 through 104-n may be collectively referred to as functional circuitry 104. Configurable interface circuitry 106-1 through 106-n may be collectively referred to as configurable interface circuitry 106. Configurable interface circuitry 108-1 through 108-n may be collectively referred to as configurable interface circuitry 108.

Functional circuitry 104-1 through 104-n may include, without limitation, fixed function circuitry/logic, configurable/programmable circuitry/logic, processor circuitry, memory, and/or combinations thereof. Functional circuitry 104-1 through 104-n, or a subset thereof may differ from one another (i.e., heterogeneous functional circuitry). Alternatively, functional circuitry 104-1 through 104-n, or a subset thereof may be similar or identical to one another (i.e., homogeneous functional circuitry).

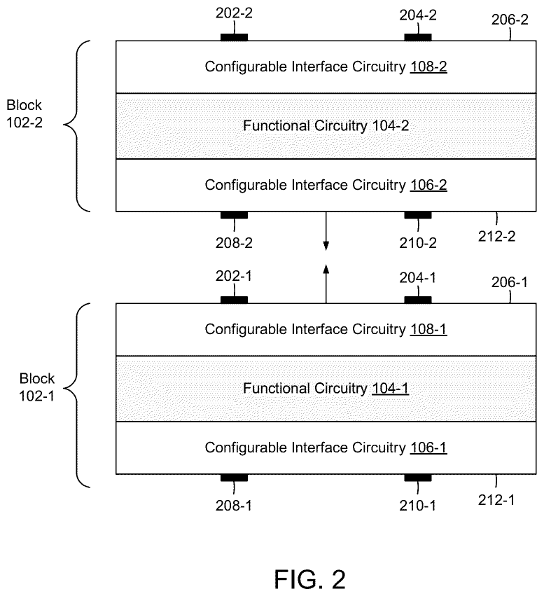

Blocks 102 may include external nodes (e.g., input and/or output nodes) exposed through surfaces thereof, such as described below with reference to FIG. 2.

FIG. 2 is a block diagram of blocks 102-1 and 102-2, according to an embodiment. In the example of FIG. 2, block 102-1 includes nodes 202-1 and 204-1 disposed over, projecting from, and/or exposed through a first surface 206-1 of block 102-1. Block 102-1 further includes nodes 208-1 and 210-1 disposed over, projecting from, and/or exposed through a second surface 212-1 of block 102-1. Similarly, block 102-2 includes nodes 202-2 and 204-2 disposed over, projecting from, and/or exposed through a first surface 206-2 of block 102-2. Block 102-2 further includes nodes 208-2 and 210-2 disposed over, projecting from, and/or exposed through a second surface 212-2 of block 102-2.

Node 202-1 may represent an output node of block 102-1, and node 208-2 may represent a corresponding input node of block 102-2. Node 204-1 may represent an input node of block 102-1, and node 210-2 may represent a corresponding output node of block 102-2. Nodes 202-1, 204-1, 208-2, and 210-2 may be positioned on respective surfaces 206-1 and 212-2 such that nodes 202-1 and 204-1 physically align with nodes 208-2 and 210-2 when block 102-2 is positioned or stacked on block 102-1. Blocks 102-1 and 102-2 may include additional input and/or output nodes.

Configurable interface circuitry 106 and configurable interface circuitry 108 interface between functional circuitry 104 of adjacent blocks 102. For example, configurable interface circuitry 108-1 couples nodes of functional circuitry 104-1 to nodes 202-1 and 204-1, and configurable interface circuitry 106-2 couples nodes of functional circuitry 104-2 to nodes 208-2 and 210-2.

Configurable interface circuitry 106-1 through 106-n and 108-1 through 108-n may be identical to one another, which may be useful to provide blocks 102 with standardized configurable interfaces to adjacent layers.

In the examples of FIGS. 1 and 2, configurable interface circuitry 108 and 106 are illustrated above and below functional circuitry 104, respectfully, for conceptual purposes. In practice, configurable interface circuitry 108 and 106 may be provided within the same IC device/die as functional circuitry 104.

In an embodiment, configurable interface circuitry 106 and configurable interface circuitry 108 include configurable loop-back or U-turn circuitry to selectively route an output node back to the respective functional circuitry 104.

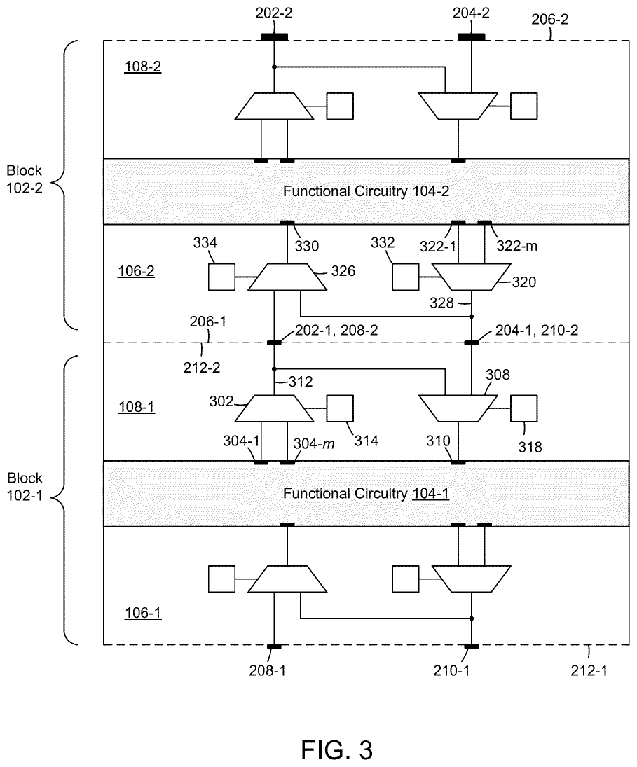

FIG. 3 is a logic diagram of blocks 102-1 and 102-2, according to an embodiment. In the example of FIG. 3, configurable interface circuitry 108-1 includes output circuitry 302 that couples a selectable one of nodes 304-1 through 304-m of functional circuitry 104-1 to output node 202-1. In another embodiment, output circuitry 302 is omitted and one or more of nodes 304 are coupled directly to one or more respective output nodes 202-1.

Configurable interface circuitry 108-1 further includes input circuitry 308 that couples a selectable one of input node 204-1 and output node 202-1 (i.e., output 312 of output circuitry 302) to an input node 310 of functional circuitry 104-1. In other words, output 312 may be looped back or returned to functional circuitry 104-1.

Looping back or returning output 312 to functional circuitry 104-1 may be referred to as a U-turn, which may be useful in one or more of a variety of situations or applications. For example, in FIG. 1, block 102-n is the upper-most block of IC device 100, and there is no adjacent block to receive an output from configurable interface circuitry 108-n or to provide an input to configurable interface circuitry 108-n. In this situation, it may be useful to repurpose configurable interface circuitry 108-n by coupling or looping-back an output node of configurable interface circuitry 108-n to functional circuitry 104-n. As another example, it may be useful to loop-back an output node of configurable interface circuitry 108 of a block 102 when the block is used in a 2D application. As another example, where block 102-1 is used in a 3D application, it may be useful to provide output 312 to adjacent block 102-2 and to input node 310.

Further in the example of FIG. 3, configurable interface circuitry 106-2 of block 102-2 includes output circuitry 320 that couples a selectable one of multiple nodes 322-1 through 322-m of functional circuitry 104-2 to output node 210-2.

Configurable interface circuitry 106-2 further includes input circuitry 326 that couples a selectable one of input node 208-2 and output node 210-2 (I.e., output 328 of output circuitry 320) to an input node 330 of functional circuitry 104-2. In other words, output 328 may be looped back or returned to functional circuitry 104-2, such as described above with respect to output 312 of configurable interface circuitry 108-1.

In the example of FIG. 3, input circuitry 308 and 326 are illustrated as 2:1 multiplexers. Input circuitry 308 and 326 are not, however, limited to 2:1 multiplexers or to multiplexers generally.

Output circuitry 302 and 320 may include n:m multiplexer circuitry that receives m inputs from respective functional circuitry 104 and provides a selectable subset of n of the m inputs to n respective output nodes, where m and n are positive integers, and m is greater than n. In the example of FIG. 3, output circuitry 302 and 320 are illustrated as 2:1 multiplexer circuitry. Other examples are provided further below.

Configurable interface circuitry 106 and/or 108 may be one-time or permanently configurable (e.g., factory-configured via E-fuses), or may be reconfigurable (e.g., at power-up/boot or dynamically during operation). In FIG. 3, output circuitry 302, input circuitry 308, output circuitry 320, and input circuitry 326 are controlled by respective configuration buffers or registers 314, 318, 332, and 334. Configuration registers 314, 318, 332, and 334 may be programmed or loaded with configuration values or logic states that are applied to control inputs of the respective circuitry (e.g., as multiplexer controls). For example, a configuration register may include an addressable memory cell, and a read output node of the memory cell may be hardwired to a control node of a multiplexer.

Configuration registers may include volatile and/or non-volatile storage circuitry. Non-volatile configuration registers may be useful to retain configuration parameters when power is removed from IC device 100. Volatile configuration registers may be useful to program configurable interface circuitry when IC device is powered up and/or to dynamically reprogram the configurable interface circuitry.

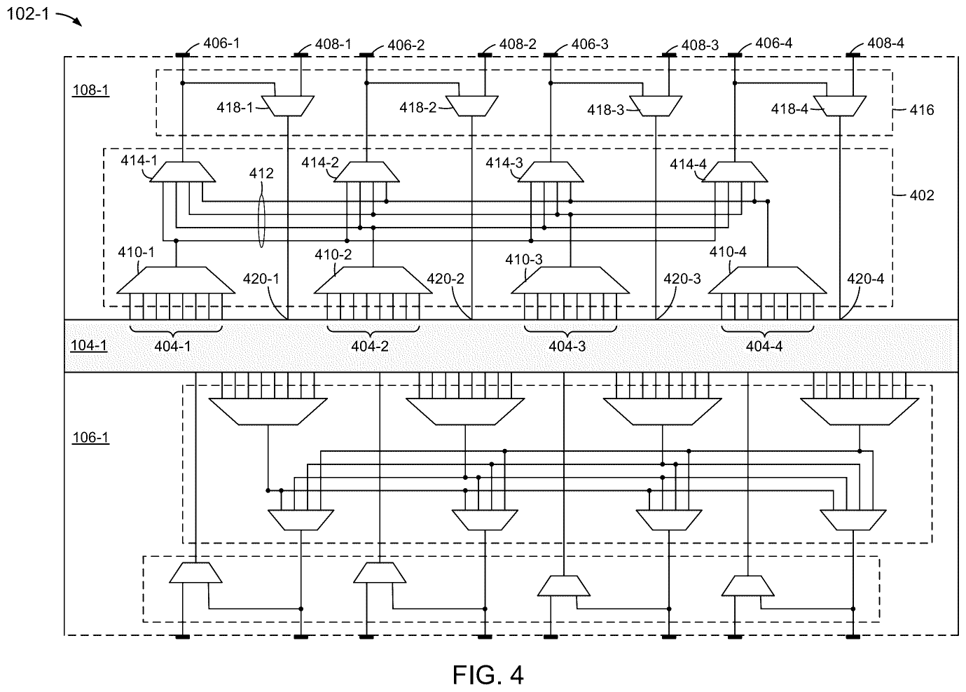

FIG. 4 is a logic diagram of block 102-1, in which output circuitry of configurable interface circuitry 106-1 and 108-1 include min multiplexer circuitry, according to an embodiment. Configurable interface circuitry 108-1 is described below. Configurable interface circuitry 106-1 may be similar or identical to configurable interface circuitry 108-1.

In the example of FIG. 4, configurable interface circuitry 108-1 includes output circuitry 402, illustrated here as min multiplexer circuitry having m inputs 404-1 through 404-4 from functional circuitry 104-1, and n outputs coupled to respective output nodes 406-1 through 406-4. In the example of FIGS. 4, m=32 and n=4. Configurable interface circuitry 108 is not, however, limited to these examples.

Output circuitry 402 includes a first set of multiplexer circuits 410-1 through 410-4, illustrated here as 8:1 multiplexer circuits that receive respective inputs 404-1 through 404-4. Outputs of multiplexer circuits 410-1 through 410-4 are coupled to respective bits or lines of a bus or crossbar 412. Multiplexer circuits 410-1 through 410-4 are separately or individually configurable.

Output circuitry 402 further includes a second set of multiplexer circuits 414-1 through 414-4, illustrated here as 4:1 multiplexer circuits. Each multiplexer circuit 414-1 through 414-4 receives all bits of crossbar 412. Each multiplexer circuit 414-1 through 414-4 is separately or individually configurable to output a selectable bit of crossbar 412 to a respective one of output nodes 406-1 through 406-4. In the example of FIG. 4, crossbar 412 may be referred to as a full crossbar or a fully connected crossbar.

In FIG. 4, configurable interface circuitry 108-1 further includes input circuitry 416, illustrated here as 2:1 multiplexer circuits 418-1 through 418-4. Multiplexer circuit 418-1 includes a first input coupled to output node 406-1, a second input coupled to an input node 408-1, and an output coupled to an input node 420-1 of functional circuitry 104-1. Multiplexer circuit 418-1 provides a selectable one of the inputs to input node 420-1. Multiplexer circuits 418-2, 418-3, and 418-4 operate in a similar fashion with respect to output nodes 406-2 through 406-4, input nodes 408-2 through 408-4, and input nodes 420-2 through 420-4 of functional circuitry 104-1.

Multiplexer circuitry illustrated in FIG. 4 may be controlled as described above with reference to FIG. 3.

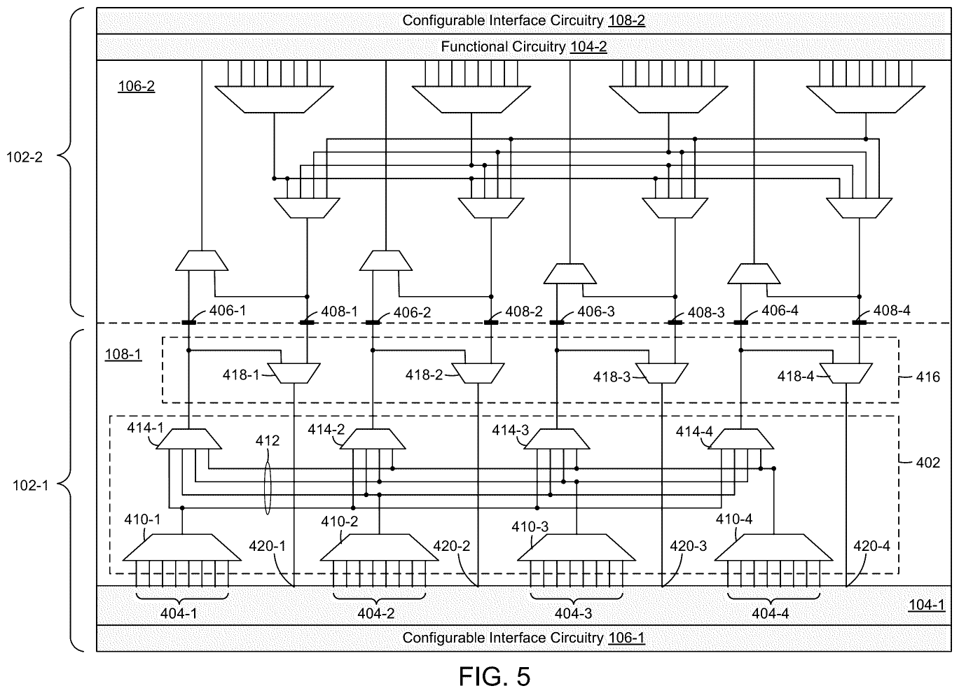

FIG. 5 is a logic diagram of blocks 102-1 and 102-2 to illustrate connections between configurable interface circuitry 108-1 of block 102-1, as illustrated as in FIG. 4, and configurable interface circuitry 106-2 of block 102-2, according to an embodiment.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method, or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Aspects of the present disclosure are described herein with reference to flowchart illustrations and/or block diagrams of methods, apparatus (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit (IC) device, comprising:
a first block of integrated circuitry that comprises functional circuitry and configurable interface circuitry, wherein the configurable interface circuitry comprises,
output circuitry configured to route a node of the functional circuitry to an output node of the first block, and
input circuitry configured to route a selectable one of the output node of the first block and an input node of the first block to the functional circuitry.

2. The IC device of claim 1, wherein:
the output node of the first block is configured to contact an input node of a second block of integrated circuitry when the second block is stacked above the first block; and
the input node of the first block is configured to contact an output node of the second block when the second block is stacked above the first block.

3. The IC device of claim 1, further comprising a second block of integrated circuitry, wherein:
the output node and the input node of the first block extend through a surface of the first block;
an output node and an input node of the second block extend through a surface of the second block; and
the output node of the first block physically aligns with the input node of the second block and the input node of the first block physically aligns with the output node of the second block when the second block is stacked above the first block such that the surfaces of the first and second blocks contact one another.

4. The IC device of claim 1, wherein the input circuitry comprises:
multiplexer circuitry configured to route a selectable one of the output node of the first block and the input node of the first block to the node of the functional circuitry.

5. The IC device of claim 1, wherein the output circuitry is further configured to route a selectable one of multiple nodes of the functional circuitry to the output node of the first block.

6. The IC device of claim 5, wherein:
the output circuitry comprises multiplexer circuitry configured to receive m inputs from the functional circuitry and to provide n outputs to n respective output nodes of the first block;
m and n are positive integers; and
m is greater than n.

7. The IC device of claim 6, wherein the multiplexer circuitry comprises:
a first set of multiplexer circuits configured to receive respective subsets of the m inputs from the functional circuitry; and
a second set of n multiplexer circuits, each configured to receive outputs of the first set of multiplexer circuits and to provide an output to a respective one of the n output nodes;
wherein the multiplexer circuits of the first and second sets of multiplexer circuits are individually controllable.

8. The IC device of claim 7, wherein:
the output circuitry further comprises a bus;
the outputs of the first set of multiplexer circuits are coupled to respective bit lines of the bus; and
the bit lines of the bus are coupled to respective inputs of each of the n multiplexer circuits.

9. The IC device of claim 8, wherein:
the first set of multiplexer circuits comprises 8:1 multiplexer circuits; and
the second set of n multiplexer circuits comprises 4:1 multiplexer circuits.

10. The IC device of claim 1, wherein:
the input circuitry is further configured to route the output node of the first block to the functional circuitry.

11. An integrated circuit (IC) device, comprising:
a stack of multiple blocks of integrated circuitry, wherein a first one of the blocks comprises functional circuitry and configurable interface circuitry, wherein the configurable interface circuitry is configured to route a first node of the functional circuitry to an output node of the first block and to route a selectable one of the output node of the first block and an input node of the first block to a second node of the functional circuitry, wherein the output node and the input node of the first block are coupled to respective input and output nodes of an adjacent one of the blocks.

12. The IC device of claim 11, wherein the configurable interface circuitry is further configured to route the output node of the first block to the second node of the functional circuitry.

13. The IC device of claim 11, wherein:
the adjacent block comprises functional circuitry and configurable interface circuitry; and
the configurable interface circuitry of the adjacent block is configured to route a first node of the functional circuitry of the adjacent block to the output node of the adjacent block and to route a selectable one of the output node of the adjacent block and the input node of the adjacent block to a second node of the functional circuitry of the adjacent block.

14. The IC device of claim 13, wherein:
the configurable interface circuitry of the first block is further configured to route the output node of the first block to the second node of the functional circuitry; and
the configurable interface circuitry of the adjacent block is further configured to route the output node of the adjacent block to the second node of the functional circuitry of the adjacent block.

15. The IC device of claim 13, wherein:
the configurable interface circuitry of the first block is further configured to route the output node of the first block to the second node of the functional circuitry; and
the configurable interface circuitry of the adjacent block is further configured to route the input node of the adjacent block to the second node of the functional circuitry of the adjacent block.

16. An integrated circuit (IC) device, comprising:
a stack of multiple blocks of integrated circuitry, wherein each block comprises functional circuitry and configurable interface circuitry, and wherein the configurable interface circuitry comprises,
output circuitry configured to route n output nodes of the functional circuitry to respective ones of n output nodes of the block; and
n blocks of input multiplexer circuitry, each comprising a first input coupled to a respective one of the n output nodes of the block, a second input coupled to a respective one of n input nodes of the block, and an output coupled to a respect one of n input nodes of the functional circuitry.

17. The IC device of claim 16, wherein the n blocks of input multiplexer circuitry comprise respective 2:1 multiplexer circuits.

18. The IC device of claim 16, wherein the output circuitry comprises:
multiplexer circuitry configured to receive m inputs from the functional circuitry and to route a selectable subset of n of the m inputs to the respective ones of the n output nodes of the block;
m and n are positive integers; and
m is greater than n.

19. The IC device of claim 16, wherein the multiplexer circuitry comprises:
a first set of multiplexer circuits configured to receive respective subsets of m inputs from the functional circuitry; and
a second set of n multiplexer circuits, each configured to receive outputs of the first set of multiplexer circuits and to provide an output to a respective one of the n output nodes;
wherein the multiplexer circuits of the first and second sets of multiplexer circuits are individually controllable.

20. The IC device of claim 19, wherein:
the output circuitry further comprises a bus;
the outputs of the first set of multiplexer circuits are coupled to respective bit lines of the bus; and
the bit lines of the bus are coupled to respective inputs of each of the n multiplexer circuits.
